(19) United States
(12) Patent Application Publication
(10) Pub. No.: US 2018/0239853 A1
(43) Pub. Date: Aug. 23, 2018

(54) RECORDING MEDIUM RECORDING MAGNETIC MATERIAL SIMULATION PROGRAM, MAGNETIC MATERIAL SIMULATION METHOD AND INFORMATION PROCESSING APPARATUS

(71) Applicant: FUJITSU LIMITED, Kawasaki-shi (JP)

(72) Inventor: Koichi Shimizu, Inagi (JP)

(73) Assignee: FUJITSU LIMITED, Kawasaki-shi (JP)

(21) Appl. No.: 15/888,128

(22) Filed: Feb. 5, 2018

(30) Foreign Application Priority Data
Feb. 22, 2017 (JP) 2017-030922

(51) Int. Cl. G06F 17/50; G06K 19/06; G01R 33/00; G11B 5/012; G11B 13/04

(52) U.S. Cl. CPC G06F 17/5018; G06K 19/06196; G11B 2005/001; G11B 5/012; G11B 13/045; G01R 33/0064

(57) ABSTRACT

A recording medium recording a magnetic material simulation program includes: acquiring a shape model including element regions of a shape of a core, property information indicating physical properties of a magnetic material of the core, and coil current information indicating a time change in a current through a coil around the core; specifying a first current density of the coil at a first time, based on the coil current information; computing, using the property information and the first current density, first index values at the first time for positions in the shape model; computing, using the first index values, a charge density of each element region; specifying a second current density of the coil at a second time, based on the coil current information; and computing, using the property information, the second current density, and the charge density, second index values at the second time for the positions.

### CROSS-REFERENCE TO RELATED APPLICATION

This application is based upon and claims the benefit of priority of the prior Japanese Patent Application No. 2017-030922, filed on Feb. 22, 2017, the entire contents of which are incorporated herein by reference.

### FIELD

The embodiment discussed herein is related to a recording medium recording magnetic material simulation program, a magnetic material simulation method, and an information processing apparatus.

### BACKGROUND

Along with improvements in the computational performance of computers, a variety of physical phenomena are being simulated using computers.

Related technology is disclosed in Japanese Laid-open Patent Publication No. 2006-351622.

### SUMMARY

According to an aspect of the embodiments, a non-transitory computer-readable recording medium recording a magnetic material simulation program causing a computer to execute a process, the process includes: acquiring a shape model that includes a plurality of element regions generated by partitioning a shape of a core, property information indicating physical properties of a magnetic material used in the core, and coil current information indicating a time change in a current flowing through a coil wrapped around the core; specifying a first current density of the coil at a first time, based on the coil current information; computing, using the property information and the first current density, a plurality of first index values related to a magnetic field at the first time, in correspondence with a plurality of positions in the shape model; computing, using the plurality of first index values, a charge density of each of the plurality of element regions; specifying a second current density of the coil at a second time after the first time, based on the coil current information; and computing, using the property information, the second current density, and the charge density of each of the plurality of element regions, a plurality of second index values related to a magnetic field at the second time, in correspondence with the plurality of positions.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 illustrates an exemplary magnetic material simulation apparatus;

FIG. 2 illustrates exemplary hardware of a simulation apparatus;

FIG. 3 illustrates an exemplary shape of a toroidal core and a coil;

FIG. 4 illustrates an exemplary relationship between the frequency of a coil and the relative permeability of a toroidal core;

FIG. 5 illustrates an exemplary structure of a magnetic material;

FIG. 6 illustrates an exemplary electric circuit equivalent to the fine structure of a magnetic material;

FIG. 7 illustrates an exemplary finite element model of a toroidal core and a coil;

FIG. 8 illustrates an exemplary assignment of variables to a finite element model;

FIG. 9 illustrates exemplary functions of a simulation apparatus;

FIG. 10 illustrates an exemplary node table and an element table;

FIG. 11 illustrates an exemplary parameter table;

FIG. 12 illustrates an exemplary result table;

FIG. 13 illustrates an exemplary procedure of a simulation;

FIG. 14 illustrates an exemplary simulation that does not account for a dimensional resonance phenomenon;

FIG. 15 illustrates an exemplary simulation that accounts for the dimensional resonance phenomenon;

FIG. 16 illustrates an exemplary magnetic flux density visualization image; and

FIG. 17 illustrates an exemplary current density visualization image.

### DESCRIPTION OF EMBODIMENT

For example, as one simulation of a physical phenomenon, for an electric component that includes a core using a magnetic material and a coil wrapped around the core, magnetic field analysis that analyzes the magnetic field produced when a current is made to flow through the coil is performed. For the magnetic field analysis simulation, the finite element method is used as the numerical analysis method.

With the finite element method, a model that partitions the shape of the analysis target into small regions called “elements” or a “mesh” is generated, and variables indicating unknown physical quantities are assigned to locations such as nodes, namely the centers of elements and vertices of elements, the edges of elements, and the like. A system of simultaneous equations (for example, a system of linear equations having a large-scale and sparse coefficient matrix) is generated from basic equations indicating the physical phenomenon and the multiple variables assigned in the model, and by solving the system of simultaneous equations, an approximate solution of the variables is obtained.

With a magnetic shield analysis method using the finite element method, an analysis routine including a first step, a second step, and a third step is executed. In the first step, a magnetic state is set for each of multiple sub-regions included in the shape of the analysis target. In the second step, the magnetic field states set in the first step and an integral equation are used to compute a boundary condition. In the third step, the boundary condition computed in the second step and the finite element method are used to update the magnetic field state of each sub-region. The above analysis routine is executed repeatedly while varying the time along the time axis. For example, the above three steps are executed again while accounting for the influence of eddy currents, and the magnetic field state of each sub-region is updated.

For example, with a core using a polycrystalline magnetic material, such as a manganese-zinc (MnZn) core, if a high-frequency current flows through a coil wrapped around the core, a dimensional resonance phenomenon may occur. The dimensional resonance phenomenon is a physical phenomenon in which the gaps existing between the multiple crystal grains included in a magnetic material behave like capacitors, thereby causing the permeability of the magnetic material to increase suddenly at specific frequencies. Since loss inside the core becomes large if the imaginary part of the permeability of the core increases, it is preferable to account for the dimensional resonance phenomenon in the magnetic field analysis of the core using a magnetic material. For example, in the magnetic field analysis of the finite element method, since the physical properties of the above magnetic material are not incorporated into the model or the basic equations, reproducing the dimensional resonance phenomenon by simulation may be difficult.

For example, a magnetic material simulation program and the like capable of improving the accuracy of magnetic field analysis of a magnetic material in which the dimensional resonance phenomenon occurs may be provided.

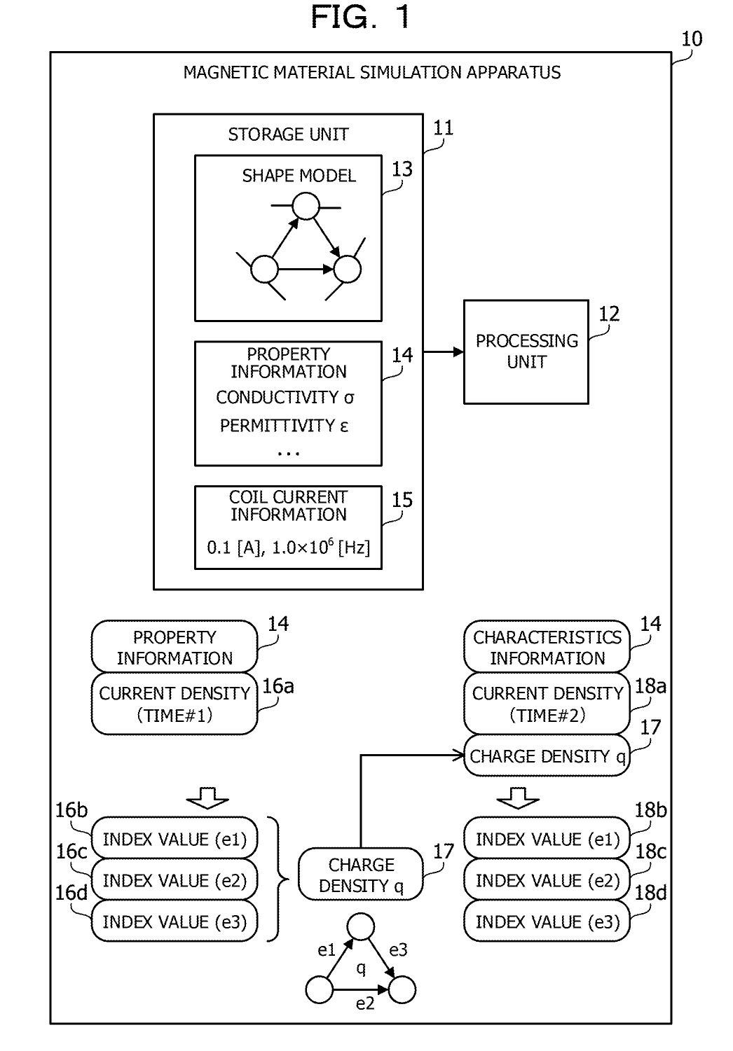

FIG. 1 illustrates an exemplary magnetic material simulation apparatus. A magnetic material simulation apparatus 10 executes a magnetic field analysis of an electric component, which includes a core using a magnetic material and a coil wrapped around the core, as a computer simulation using the finite element method. The magnetic material simulation apparatus 10 may be client apparatus operated by a user, or a server apparatus.

The magnetic material simulation apparatus 10 includes a storage unit 11 and a processing unit 12. The storage unit 11 is a volatile storage device such as random access memory (RAM), or a non-volatile storage device such as a hard disk drive (HDD) or flash memory. The processing unit 12 is a processor such as a central processing unit (CPU) or a digital signal processor (DSP), for example. The processing unit 12 may also include an electronic circuit for a specific purpose, such as an application-specific integrated circuit (ASIC) or a field-programmable gate array (FPGA). The processor executes programs stored in memory such as RAM. For example, a magnetic material simulation program is executed. Note that a set of multiple processors may be called a “multi-processor” or simply a “processor”.

The storage unit 11 stores a shape model 13, property information 14, and coil current information 15 used in the simulation. The shape model 13, the property information 14, and the coil current information 15 may be user-created, or generated by software such as modeling software. Additionally, the shape model 13, the property information 14, and the coil current information 15 may be created by the magnetic material simulation apparatus 10, or acquired from another apparatus.

The shape model 13 is a finite element model that includes multiple element regions generated by partitioning the shape of the core. Examples of the core include donut-shaped and toroidal cores. The shape model 13 may additionally include element regions corresponding to the shape of the coil wrapped around the core, element regions corresponding to the space around the core and the coil, and the like. The multiple element regions are two-dimensional or three-dimensional regions of the same type, such as triangles, quadrilaterals, tetrahedrons, or hexahedrons, for example.

The property information 14 indicates the physical properties of the magnetic material used in the core. The property information 14 includes the conductivity and the permittivity of the magnetic material, for example. Also, the property information 14 includes, for example, size information indicating the relationship between the thickness of each of the crystal grains included in the magnetic material, and the thickness of the grain boundary layer existing between these multiple crystal grains. The coil current information 15 indicates change over time of the current flowing through the coil wrapped around the core. The change over time of the current may be expressed continuously by an amplitude or a frequency, or may be expressed discretely as a current density at each time.

The processing unit 12 specifies a current density 16a of the current flowing through the coil at a time #1 in the simulation, based on the coil current information 15. In the case in which the coil current information 15 is expressed by amplitude and frequency, the processing unit 12 obtains the current density 16a at the time #1 by calculation. In the case in which the coil current information 15 is expressed discretely, the processing unit 12 selects the current density 16a at the time #1 from among the current densities at multiple times.

The processing unit 12 uses the property information 14 and the current density 16a to compute multiple index values related to the magnetic field at the time #1 in association with multiple positions on the shape model 13. The multiple positions on the shape model 13 are positions specified based on the multiple element regions included in the shape model 13, such as the centers of element regions, nodes enclosing the element regions, and edges enclosing the element regions. For example, the processing unit 12 computes an index value 16b with respect to an edge e1 enclosing an element region, computes an index value 16c with respect to an edge e2, and computes an index value 16d with respect to an edge e3. The index values related to the magnetic field are numerical values indicating the physical phenomenon to be computed by the simulation, and are vector potentials or the like, for example. For example, from a designated calculation formula #1, the property information 14, and the current density 16a, the processing unit 12 generates a system of simultaneous equations including multiple variables assigned to multiple positions on the shape model 13, and by solving the system of simultaneous equations, computes multiple index values as the solution of the multiple variables.

The processing unit 12 uses the multiple index values at the time #1, including the index values 16b, 16c, and 16d, to compute the charge density of the charge accumulated in each of the multiple element regions included in the shape model 13. For example, the processing unit 12 computes a charge density 17 of a certain element region using the index values 16b, 16c, and 16d corresponding to the edges e1, e2, and e3 enclosing the element region. The charge density is computed in accordance with a designated calculation formula #2 different from the calculation formula #1 above, for example. At this time, the processing unit 12 may use the multiple index values at the time #1 to compute the current density of the current flowing through each of the multiple element regions included in the shape model 13, and from the current density, compute the charge density of each of the multiple element regions.

The processing unit 12 specifies a current density 18a of the current flowing through the coil at a time #2 after the time #1 in the simulation, based on the coil current information 15. The processing unit 12 uses the property information 14, the current density 18a, and the charge density of each of the multiple element regions to compute multiple index values related to the magnetic field at the time #2 in association with multiple positions on the shape model 13. For example, the processing unit 12 computes an index value 18b with respect to the edge e1, computes an index value 18c with respect to the edge e2, and computes an index value 18d with respect to the edge e3.

The index values 18b, 18c, and 18d are of a similar type to the index values 16b, 16c, and 16d, and are vector potentials or the like, for example. The calculation formula used at this point is basically similar to the calculation formula #1 above. However, the charge density 17 computed during the simulation at the time #1 is used in the calculation formula. For example, from the property information 14, the current density 18a, and the charge density of each of the multiple element regions, the processing unit 12 generates a system of simultaneous equations including the multiple variables above, and by solving the system of simultaneous equations, computes multiple index values as the solution of the multiple variables.

According to the magnetic material simulation apparatus 10, in a magnetic material simulation using the finite element method, the charge density of the charge accumulated in each element region is computed from the simulation result at the time #1. The computed charge density is used in the simulation at the time #2 after the time #1 (for example, immediately after the time #1). With this arrangement, it is possible to reproduce the dimensional resonance phenomenon, in which the gaps existing between the multiple crystal grains included in the magnetic material behave like capacitors, thereby causing the permeability to increase suddenly at specific frequencies. Thus, the accuracy of the magnetic material simulation is improved.

For example, a simulation apparatus 100 executes, as a computer simulation, magnetic field analysis of an electric component including a MnZn toroidal core and a coil.

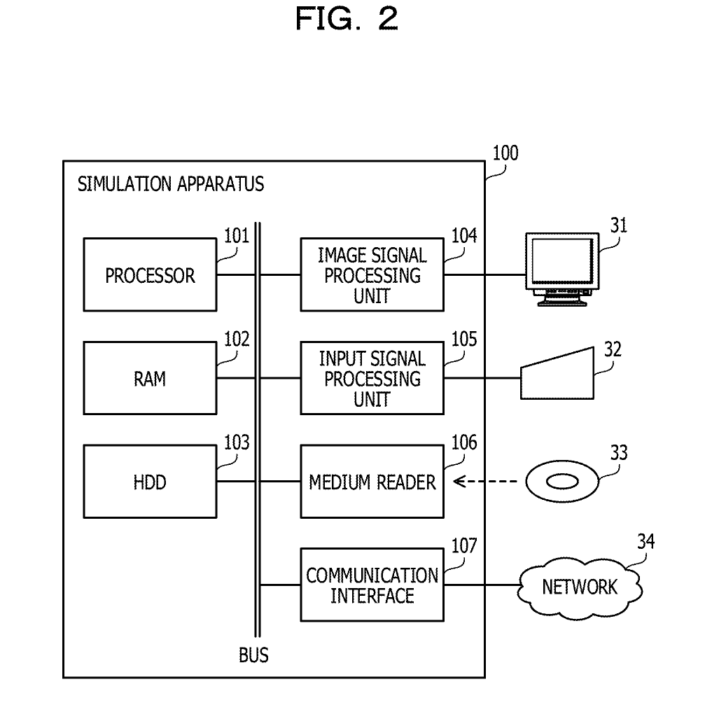

FIG. 2 illustrates exemplary hardware of a simulation apparatus. The simulation apparatus 100 includes a CPU 101, RAM 102, an HDD 103, an image signal processing unit 104, an input signal processing unit 105, a media reader 106, and a communication interface 107. The above units are coupled to a bus.

The CPU 101 is a processor including a computational circuit that executes the instructions of a program. The CPU 101 loads a program and at least partial data stored in the HDD 103 into the RAM 102, and executes the program. Note that the CPU 101 may also be provided with multiple processor cores, the simulation apparatus 100 may also be provided with multiple processors, and the following processes may also be executed in parallel using multiple processors or processor cores. Also, a set of multiple processors may be called a “multi-processor” or a “processor”.

The RAM 102 is volatile semiconductor memory that temporarily stores programs executed by the CPU 101 and data used in computations by the CPU 101. The simulation apparatus 100 may also be provided with a type of memory other than RAM, and may also be provided with multiple types of memory.

The HDD 103 is a non-volatile storage device that stores an operating system (OS), software programs such as application software, and data. The simulation apparatus 100 may be provided with another type of storage device, such as flash memory or a solid-state drive (SSD), and may also be provided with multiple non-volatile storage devices.

The image signal processing unit 104, following instructions from the CPU 101, outputs an image to a display 31 coupled to the simulation apparatus 100. For the display 31, a display of arbitrary type may be used, such as a cathode ray tube (CRT) display, a liquid crystal display (LCD), a plasma display, or an organic electro-luminescence (OEL) display.

The input signal processing unit 105 acquires an input signal from an input device 32 coupled to the simulation apparatus 100, and outputs to the CPU 101. For the input device 32, a pointing device such as a mouse, a touch panel, a touchpad, or a trackball, a keyboard, a remote controller, buttons, switches, or the like may be used. Multiple types of input devices may be coupled to the simulation apparatus 100.

The media reader 106 is a reading device that reads programs and data recorded onto a recording medium 33. For the recording medium 33, for example, a magnetic disk, an optical disc, a magneto-optical (MO) disc, semiconductor memory, or the like may be used. Magnetic disks include flexible disk (FD) and HDD. Optical discs include Compact Disc (CD) and Digital Versatile Disc (DVD).

For example, the media reader 106 copies programs and data read from the recording medium 33 to another recording medium, such as the RAM 102 or the HDD 103. A read-out program is executed by the CPU 101, for example. Note that the recording medium 33 may also be a portable recording medium, and may be used to distribute programs and data. The recording medium 33 and the HDD 103 are sometimes called computer-readable recording media.

The communication interface 107 is coupled to a network 34, and is an interface that communicates with other apparatus via the network 34. The communication interface 107 may be a wired communication interface coupled by a cable to a communication apparatus such as a switch, or a wireless communication interface coupled by a wireless link to a base station.

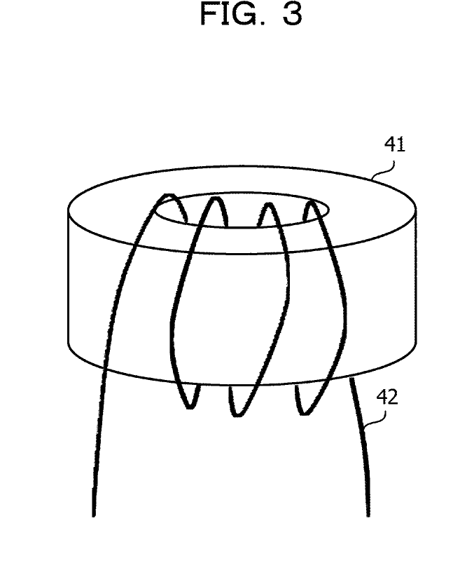

FIG. 3 is a diagram illustrating an exemplary shape of a toroidal core and a coil. The electric component to be analyzed includes a toroidal core 41 and a coil 42. In the toroidal core 41, a polycrystalline magnetic material, namely a MnZn sintered magnet, is used. The sintered magnet is created by heating and compacting magnetic powder at high temperature. The toroidal core 41 has a donut shape with a central hole. The coil 42 is an electric wire wrapped around the toroidal core 41. The coil 42 is wrapped spirally so as to pass through the hole of the toroidal core 41. The coil 42 touches the surface of the toroidal core 41, for example. Alternating current is supplied from the outside to the coil 42. The current flowing through the coil 42 may be a high-frequency current.

The relative permeability of the toroidal core 41 (the ratio of the permeability of the toroidal core 41 with respect to the permeability of a vacuum) changes according to the frequency of the current flowing through the coil 42. Specifically, if current of a specific, comparatively high frequency flows through the coil 42, the dimensional resonance phenomenon, in which the relative permeability increases suddenly, occurs in the toroidal core 41. The dimensional resonance phenomenon occurs due to the gaps (grain boundary layer) that exist between the multiple crystal grains included in the magnetic material behaving like capacitors.

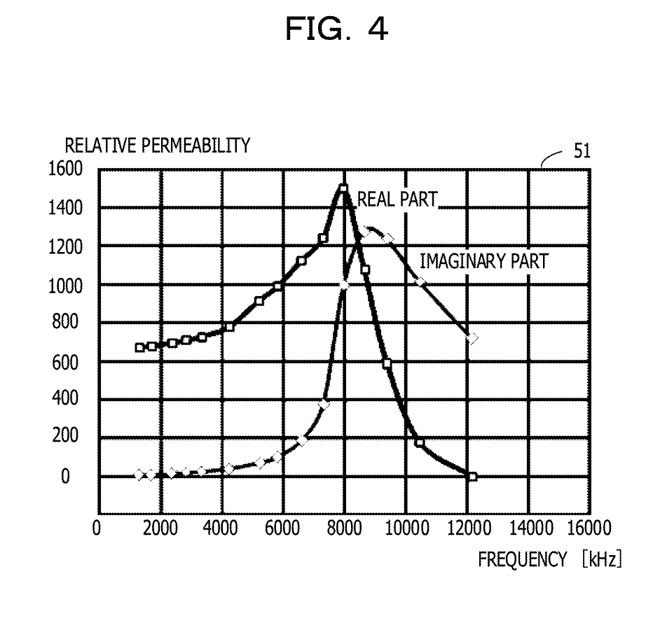

FIG. 4 illustrates an exemplary relationship between the frequency of the coil and the relative permeability of the toroidal core. The graph 51 illustrates the relationship between the frequency of current flowing through the coil 42 and the relative permeability of the toroidal core 41. As illustrated in the graph 51, each of the real part and the imaginary part of the relative permeability of the toroidal core 41 has a peak at a specific, comparatively high frequency. For example, the real part of the relative permeability takes a maximum value of approximately 1500 at approximately 8000 kHz. Also, for example, the imaginary part of the relative permeability takes a maximum value of approximately 1300 at approximately 9000 kHz.

If the imaginary part of the relative permeability of the toroidal core 41 becomes large, the loss per unit volume of the toroidal core 41 increases. For this reason, it is preferable for the designer of the electric component to ascertain the relationship between the frequency of the coil 42 and the loss of the toroidal core 41. The simulation apparatus 100 performs magnetic field analysis reflecting such a dimensional resonance phenomenon.

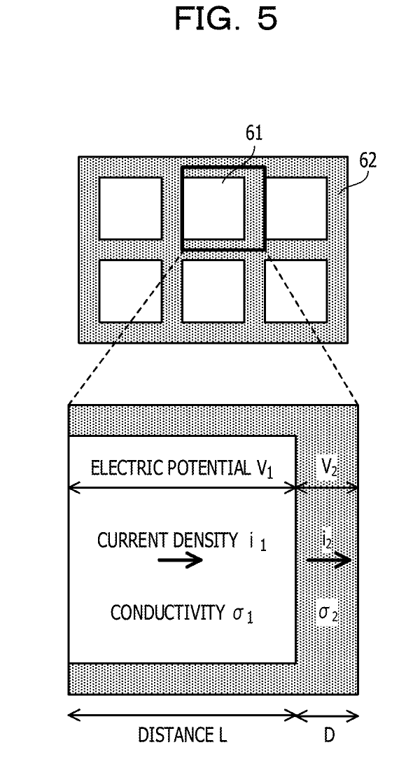

FIG. 5 illustrates an exemplary fine structure of a magnetic material. In the magnetic material used in the toroidal core 41, there are formed multiple crystal grains, including a crystal grain 61, and a grain boundary layer 62 existing between these multiple crystal grains. The crystal grain 61 has comparatively high conductivity, and comparatively low resistivity. The grain boundary layer 62 has comparatively low conductivity, that is, comparatively high resistivity. By enclosing the crystal grain 61 having high conductivity with the grain boundary layer 62 having low conductivity, eddy currents are suppressed. However, if a specific high-frequency current flows through the coil 42, eddy currents occur readily in the crystal grain 61.

Assume that inside the magnetic material, multiple crystal grains of uniform size are arranged regularly. When modeling the magnetic material, a single crystal grain and the grain boundary layer existing around the crystal grain are extracted as a single unit region. For the sake of simplicity, a two-dimensional unit region will be considered. As illustrated in FIG. 5, the crystal grain 61 and the grain boundary layer 62 enclosing three edges of the crystal grain 61 are extracted as a single unit region. The thickness of the grain boundary layer in a certain direction corresponds to the distance between adjacent crystal grains.

For such a unit region, potential differences V₁ and V₂, current densities i₁ and i₂, conductivities σ₁ and σ₂, and distances L and D are defined. The potential difference V₁ is the difference in potential between one edge and the opposite edge of the crystal grain 61. The potential difference V₂ is the difference in potential between one edge and the opposite edge of the grain boundary layer 62 (the edge of the crystal grain adjacent to one edge of the crystal grain 61). The current density i₁ is the current density inside the crystal grain 61. The current density i₂ is the current density inside the grain boundary layer 62. The conductivity σ₁ is the conductivity of the crystal grain 61. The conductivity σ₂ is the conductivity of the grain boundary layer 62. The distance L is the distance between one edge and the opposite edge of the crystal grain 61, or in other words, the thickness of the crystal grain 61. The distance D is the distance between one edge and the opposite edge of the grain boundary layer 62, or in other words, the thickness of the grain boundary layer 62.

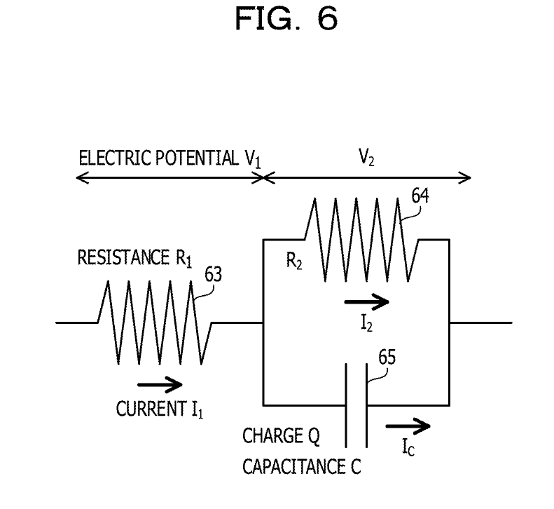

The electric properties of the unit region may be expressed by an equivalent electric circuit. FIG. 6 is a diagram illustrating an exemplary electric circuit equivalent to the fine structure of the magnetic material. In the above unit region of the magnetic material, the grain boundary layer 62 may behave like a capacitor that accumulates charge. Accordingly, the electric properties of the above unit region is equivalent to the electric circuit of FIG. 6. The electric circuit includes resistor circuits 63 and 64, and a capacitor 65. The resistor circuit 64 and the capacitor 65 are coupled in parallel to each other to the resistor circuit 63. The resistor circuit 63 corresponds to the crystal grain 61, while the resistor circuit 64 and the capacitor 65 correspond to the grain boundary layer 62.

For example, the potential difference between one end and the other end of the resistor circuit 63 is V₁. The potential difference between one end and the other end of the resistor circuit 64 is V₂. Furthermore, for the electric circuit of FIG. 6, resistances R₁ and R₂, currents I₂, I₂, and I_{C}, a charge Q, and a capacitance C are defined. The resistance R₁ is the resistance of the resistor circuit 63, that is, the resistance of the crystal grain 61 (in units of ohms (Ω)). The resistance R₂ is the resistance of the resistor circuit 64, that is, the resistance of the grain boundary layer 62. The current I₁ is the current flowing through the resistor circuit 63. The current I₂ is the current flowing through the resistor circuit 64. The current I_{C} is the current flowing through the capacitor 65, and corresponds to I₁-I₂. The charge Q is the charge accumulated in the capacitor 65, that is, the charge of the grain boundary layer 62 (in units of coulombs (C)). The capacitance C is the capacitance (electrostatic capacitance) of the capacitor 65, that is, the capacitance of the grain boundary layer 62 (in units of farads (F)). Also, a charge density q is defined. The charge density q is the charge density of the capacitor 65, that is, the charge density of the grain boundary layer 62 (in units of C/m²)).

Based on the above electric circuit model, the resistances R₁ and R₂, the capacitance C, and the charge Q may be defined as in the Formulas (1) to (4). In Formula (3), εᵣ is the relative permittivity of the grain boundary layer 62, while ε₀ is the permittivity of a vacuum.

$${R}_{1} = \frac{1}{{σ}_{1} L} \qquad ( 1 )$$

The total potential V, which is the sum of the potential difference V₁ of the crystal grain 61 and the potential difference V₂ of the grain boundary layer 62, is computed from the above Formulas (1) and (2), as in Formula (5). Provided that E is the average electric field of the unit region, since the distance D is sufficiently smaller than the distance L, the total potential V is approximated as in Formula (6). The average electric field E is computed from Formulas (5) and (6), as in Formula (7). In Formula (7), the dimensional ratio r is the ratio of the distance D of the grain boundary layer 62 with respect to the distance L of the crystal grain 61.

$$\begin{matrix}V = {V}_{1} + {V}_{2} = {R}_{1} {I}_{1} + {R}_{2} {I}_{2} = \frac{1}{{σ}_{1} L} {i}_{1} {L}^{2} + \frac{D}{{σ}_{2} {L}^{2}} {i}_{2} {L}^{2} & ( 5 ) \\ V = E ( L + D ) \approx EL & ( 6 ) \\ E = \frac{1}{{σ}_{1}} {i}_{1} + \frac{r}{{σ}_{2}} {i}_{2} where r = \frac{D}{L} & ( 7 )\end{matrix}$$

Formula (8) is established as a formula of current conservation indicating the relationship among the currents I₁, I₂, and I_{C} described above, and from Formula (8) and Formula (4), Formula (9) is established as a formula of current density conservation.

$$\begin{matrix}{I}_{1} = {I}_{2} + {I}_{C} = {i}_{2} {L}^{2} + \frac{dQ}{dt} & ( 8 ) \\ {i}_{1} = {i}_{2} + \frac{dq}{dt} & ( 9 )\end{matrix}$$

Formula (10) is established from the relationship in which the potential difference across the resistor circuit 64 and the potential difference across the capacitor 65 are both V₂. From Formula (10) and Formulas (2) to (4), Formula (11) is established between the current density i₂ and the charge density q. If Formula (11) is substituted into the current density i₂ of Formula (7), the average electric field E is computed as in Formula (12). If Formulas (12) is rearranged, the current density i₁ is computed as in Formula (13).

$$\begin{matrix}{V}_{2} = {R}_{2} {I}_{2} = \frac{Q}{C} & ( 10 ) \\ {i}_{2} = \frac{q}{{ɛ}_{r} {ɛ}_{0}} {σ}_{2} & ( 11 ) \\ E = \frac{{i}_{1}}{{σ}_{1}} + \frac{r}{{ɛ}_{r} {ɛ}_{0}} q & ( 12 ) \\ {i}_{1} = {σ}_{1} ( E - \frac{r}{{ɛ}_{r} {ɛ}_{0}} q ) & ( 13 )\end{matrix}$$

The charge density q of the charge accumulated in the grain boundary layer 62 may be computed by time-integrating the difference between the current density i₁ of the crystal grain 61 and the current density i₂ of the grain boundary layer 62. Thus, utilizing Formula (11), the charge density q is computed as in Formula (14). In so doing, the relationship between the current density i₁ of the crystal grain 61 and the charge density q of the grain boundary layer 62 is defined.

$$q = {\int }_{0}^{t} ( {i}_{1} - {i}_{2} ) dt = {\int }_{0}^{t} ( {i}_{1} - \frac{{σ}_{2}}{{ɛ}_{r} {ɛ}_{0}} q ) dt \qquad ( 14 )$$

In the case in which the capacitance effect of the grain boundary layer 62 is not considered, Formulas (15) and (16) may be used as the basic equations of magnetic field analysis. Formula (15) is a governing equation of a magnetic field, while Formula (16) is a formula of current density conservation. In Formulas (15) and (16), σ is the conductivity, A is the vector potential, and φ is the scalar potential. Also, in Formula (15), μ is the permeability, and J₀ is the current density of the coil 42. Note that in the following, a variable that takes a vector value in a formula may be denoted with a vector symbol. The vector potential A of Formulas (15) and (16) as well as the current density J₀ of Formula (15) take vector values. In contrast, the scalar potential φ of Formulas (15) and (16) takes a scalar value. However, in the following, a certain variable may not be clearly indicated as taking a scalar value or a vector value.

$$\begin{matrix}σ ( \frac{\partial \vec{A}}{\partial t} + ∇ ϕ ) + ∇ \times \frac{1}{μ} ∇ \times \vec{A} = {\vec{J}}_{0} & ( 15 ) \\ ∇ \cdot ( σ \frac{\partial \vec{A}}{\partial t} + ∇ ϕ ) = 0 & ( 16 )\end{matrix}$$

The eddy current density i of the unit region is computed as in Formula (17), using the vector potential A and the scalar potential φ determined by Formulas (15) and (16). The eddy current density i takes a vector value. The eddy current density i is defined centered on the unit region, and is defined as the current density produced in accordance with the average electric field E. In other words, the relationship i=σE is established.

$$\vec{i} = - σ ( \frac{\partial \vec{A}}{\partial t} + ∇ ϕ ) \qquad ( 17 )$$

Next, the above basic equation is rearranged to account for the capacitance effect of the grain boundary layer 62. Based on the fine structure of FIG. 5, the crystal grain 61 is sufficiently larger than the grain boundary layer 62, and the current density i₁ of the crystal grain 61 occupies the majority of the current density for the unit region overall. For this reason, the current density i₁ and the conductivity σ₁ of the crystal grain 61 appearing in Formula (13) may be treated as the current density and the conductivity representative of the unit region, and may be considered to be defined centered on the unit region. Accordingly, the eddy current density i of the unit region is approximated by the current density i₁ computed as in Formula (18). The current density i₁ depends on the vector potential A, the scalar potential φ, and the charge density q. Unlike Formula (17), a charge density q term has been added to Formula (18). The current i₁ and the charge density q are defined at the center position of the unit region.

$${\vec{i}}_{1} = - {σ}_{1} ( \frac{\partial \vec{A}}{\partial t} + ∇ ϕ + \frac{r}{{ɛ}_{r} {ɛ}_{0}} \vec{q} ) \qquad ( 18 )$$

Applying the current density i₁ and the conductivity σ₁, the governing equation of the magnetic field of Formula (15) may be rearranged as in Formula (19). Unlike Formula (15), a charge density q term has been added to Formula (19). Also, the formula of current density conservation of Formula (16) may be rearranged as in Formula (20). Unlike Formula (16), a charge density q term has been added to Formula (20).

$$\begin{matrix}{σ}_{1} ( \frac{\partial \vec{A}}{\partial t} + ∇ ϕ + \frac{r}{{ɛ}_{r} {ɛ}_{0}} \vec{q} ) + ∇ \times \frac{1}{μ} ∇ \times \vec{A} = {\vec{J}}_{0} & ( 19 ) \\ ∇ \cdot {σ}_{1} ( \frac{\partial \vec{A}}{\partial t} + ∇ ϕ + \frac{r}{{ɛ}_{r} {ɛ}_{0}} \vec{q} ) = 0 & ( 20 )\end{matrix}$$

From Formula (14) described above, Formula (21) is established for the current density i₁ and the charge density q, each of which takes a vector value. If the time integral of Formula (21) is expressed as a numerical integration in the time direction, Formula (22) is established. In Formula (22), qⁿ is the charge density at a time n inside the simulation, and qⁿ⁺¹ is the charge density at a time n+1 (the next time after the time n) inside the simulation. In Formula (22), Δt is the minimum unit of the passage of time inside the simulation, and is the difference between the time n and the time n+1. In Formula (22), Δt has meaning as the time period over which to observe change in the charge density J₀ of the coil 42. By rearranging Formula (22), Formula (23) is established. The charge density q at the time n+1 depends on the current density i₁ at the time n+1, and the charge density q at the immediately preceding time n.

$$\begin{matrix}\vec{q} = {\int }_{0}^{t} ( {\vec{i}}_{1} - \frac{{σ}_{2}}{{ɛ}_{r} {ɛ}_{0}} \vec{q} ) dt & ( 21 ) \\ {\vec{q}}^{n + 1} = {\int }_{0}^{t + Δ t} ( {\vec{i}}_{1} - \frac{{σ}_{2}}{{ɛ}_{r} {ɛ}_{0}} \vec{q} ) dt = {\vec{q}}^{n} + ( {\vec{i}}_{1} - \frac{{σ}_{2}}{{ɛ}_{r} {ɛ}_{0}} {\vec{q}}^{n + 1} ) Δ t & ( 22 ) \\ {\vec{q}}^{n + 1} = \frac{{\vec{q}}^{n} + {\vec{i}}_{1} Δ t}{1 + \frac{{σ}_{2}}{{ɛ}_{r} {ɛ}_{0}} Δ t} & ( 23 )\end{matrix}$$

The simulation apparatus 100 is able to use the above Formulas (18) to (20) and (23) as the basic equations of magnetic field analysis that account for the capacitance effect of the grain boundary layer 62. For example, from the charge density J₀ at the time n+1 and the charge density q at the time n, the vector potential A at the time n+1 and the scalar potential φ at the time n+1 are computed in accordance with Formulas (19) and (20). Next, from the vector potential A at the time n+1, the scalar potential φ at the time n+1, and the charge density q at the time n, the current density i₁ at the time n+1 is computed in accordance with Formula (18). Subsequently, from the current density i₁ at the time n+1 and the charge density q at the time n, the charge density q at the time n+1 is computed in accordance with Formula (23). By repeatedly executing the above at multiple discrete times along the time axis, magnetic field analysis that accounts for the capacitance effect becomes possible.

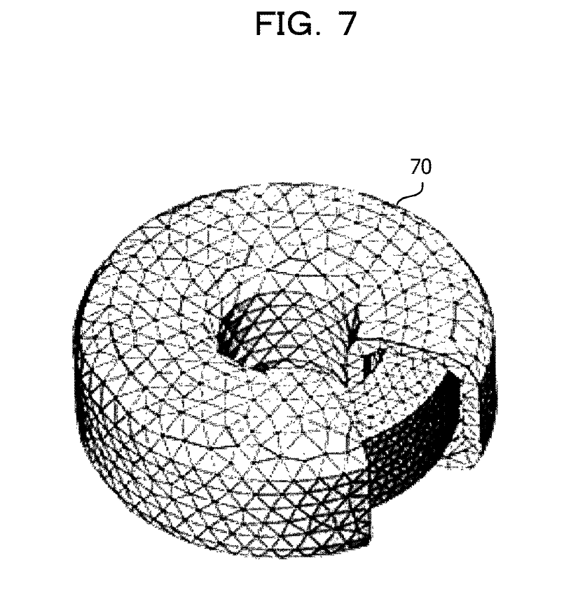

FIG. 7 illustrates an exemplary finite element model of a toroidal core and a coil. The shape of the electric component that includes the toroidal core 41 and the coil 42 is expressed by a model 70. The model 70 is a set of elements, which are subdivided regions. The model 70 includes elements indicating the region of the toroidal core 41, and elements indicating the region of the coil 42. The model 70 may also include elements indicating air regions around the toroidal core 41 and the coil 42.

Each element is a closed region enclosed by multiple nodes and multiple edges. The shape of each element is a triangle, a quadrilateral, a tetrahedron, a hexahedron, or the like, for example. A single triangular element is formed by three nodes and three edges. A single tetrahedral element is formed by four nodes and six edges. The same node may be shared by two or more elements. Also, the same edge may be shared by two or more elements.

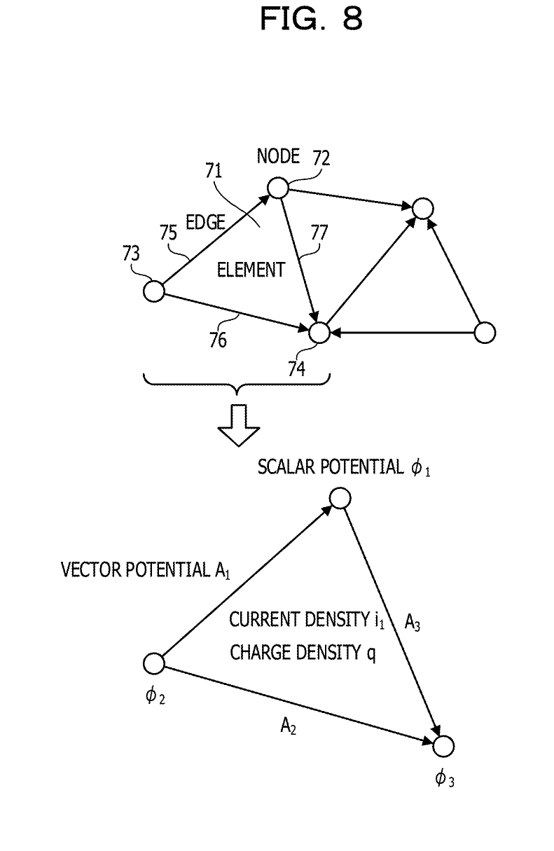

FIG. 8 illustrates an exemplary assignment of variables to a finite element model. Herein, for the sake of simplicity, a two-dimensional triangular element 71 will be considered. The element 71 is formed by nodes 72, 73, and 74, and by edges 75, 76, and 77. The edge 75 is a line segment joining the node 72 and the node 73. The edge 76 is a line segment joining the node 73 and the node 74. The edge 77 is a line segment joining the node 74 and the node 72.

If given the model 70 to use in magnetic field analysis, the simulation apparatus 100 assigns an unknown vector potential A to each of the multiple edges included in the model 70. Also, the simulation apparatus 100 assigns an unknown scalar potential φ to each of the multiple nodes included in the model 70. The unknown vector potentials A and the unknown scalar potentials φ correspond to the variables of a system of simultaneous equations. Each of the assigned vector potentials A and scalar potentials φ takes a vector value and a scalar value, respectively.

Through simulation, an approximate solution to the vector potentials A and the scalar potentials φ is computed. The current density i₁ that takes a vector value and the charge density q that takes a vector value are assigned to the center position of each element. As described earlier, the current density i₁ and the charge density q depend on the vector potential A and the scalar potential φ. The current density i₁ and the charge density q of a certain element are computed from the scalar potentials φ assigned to the nodes forming the element, and the vector potentials A assigned to the edges forming the element.

For example, an unknown scalar potential φ₁ is assigned to the node 72. An unknown scalar potential φ₂ is assigned to the node 73. An unknown scalar potential φ₃ is assigned to the node 74. Also, an unknown vector potential A₁ is assigned to the edge 75. An unknown vector potential A₂ is assigned to the edge 76. An unknown vector potential A₃ is assigned to the edge 77. Also, the current density i₁ and the charge density q are assigned to the center of the element 71. The current density i₁ and the charge density q depend on A₁, A₂, and A₃, and also on φ₁, φ₂, and φ₃.

A method of generating a system of simultaneous equations will be described. The vector potential of a certain element is computed as in Formula (24). In Formula (24), A on the left-hand side is a vector potential defined at the center of the element, and takes a vector value. Also, nₑ is the number of edges forming a single element. In the case in which the element is a two-dimensional triangle, nₑ=3, and in the case in which the element is a three-dimensional tetrahedron, nₑ=6. Aᵢ is the unknown vector potential assigned to the ith edge, and takes a scalar value. N^{e}ᵢ is an interpolation function with respect to the ith edge, and has vector-like properties. The vector potential A of each element is computed from Aᵢ, the number of which is nₑ, and from N^{e}ᵢ, the number of which is nₑ.

$$\vec{A} = {\sum }_{i = 1}^{{n}_{e}} {\vec{N}}_{i}^{e} {A}_{i} \qquad ( 24 )$$

The scalar potential of a certain element is computed as in Formula (25). In Formula (25), φ on the left-hand side is a scalar potential defined at the center of the element, and takes a scalar value. Also, nₙ is the number of nodes forming a single element. In the case in which the element is a two-dimensional triangle, nₙ=3, and in the case in which the element is a three-dimensional tetrahedron, nₙ=4. Also, φᵢ is the unknown scalar potential assigned to the ith node, and takes a scalar value. Nⁿᵢ is an interpolation function with respect to the ith node, and has scalar-like properties. The scalar potential φ of each element is computed from φᵢ, the number of which is nₙ, and from Nⁿᵢ, the number of which is N.

$$ϕ = {\sum }_{i = 1}^{{n}_{n}} {N}_{i}^{n} {ϕ}_{i}$$

In Formula (19), which is one of the basic equations, Formula (24) is substituted in for the vector potential A, and Formula (25) is substituted in for the scalar potential φ. Subsequently, both sides of Formula (19) are multiplied by a weighting function w defined by Formula (26), and spatially integrated. In Formula (26), N^{e}ᵢ is an interpolation function similar to Formula (24), while w^{e}ᵢ is a scalar value expressing the weight of an edge. By the above calculation, Formula (27) is computed. From Formula (27), there is generated a system of simultaneous equations including a number of equations corresponding to the number of vector potentials Aᵢ, that is, the number of edges included in the model 70.

$$\begin{matrix}\vec{w} = {\sum }_{i = 1}^{{n}_{e}} {w}_{i}^{e} {\vec{N}}_{i}^{e} & ( 26 ) \\ {\sum }_{i = 1}^{{n}_{e}} {\sum }_{j = 1}^{{n}_{e}} {\int }_{V} {w}_{i}^{e} {\vec{N}}_{i}^{e} \cdot \{ {σ}_{1} ( \frac{\partial {\vec{N}}_{j}^{e} {A}_{j}}{\partial t} + ∇ ϕ + \frac{r}{{ɛ}_{r} {ɛ}_{0}} \vec{q} ) + ∇ \times \frac{1}{μ} ∇ \times {\vec{N}}_{j}^{e} {A}_{j} \} dV = {\sum }_{i = 0}^{{n}_{e}} {\int }_{V} {w}_{i}^{e} {\vec{N}}_{i}^{e} \cdot {\vec{J}}_{0} dV & ( 27 )\end{matrix}$$

The first term on the left side of Formula (27) may be expanded as in Formula (28) using matrices. Herein, {w^{e}} is a matrix (row vector) of the size 1×(number of edges), [N^{e}·N^{e}] is a matrix of the size (number of edges)×(number of edges), and {Aⁿ⁺¹-Aⁿ} is a matrix (column vector) of the size (number of edges)×1. The second term on the left side of Formula (27) may be expanded as in Formula (29) using matrices. Herein, [N^{e}·∇Nⁿ] is a matrix of the size (number of edges)×(number of nodes), and {φⁿ⁺¹} is a matrix of the size (number of nodes)×1. The third term on the left side of Formula (27) may be expanded as in Formula (30) using a matrix. Herein, [N^{e}·q] is a matrix of the size (number of edges)×1. The fourth term on the left side of Formula (27) may be expanded as in Formula (31) using matrices. Herein, [V×N^{e}·V×N^{e}] is a matrix of the size (number of edges)×(number of edges), and {Aⁿ⁺¹} is a matrix of the size (number of edges)×1. The right side of Formula (27) may be expanded as in Formula (32) using a matrix. Herein, [N^{e}·J₀] is a matrix of the size (number of edges)×1.

$$\begin{matrix}\frac{{σ}_{1}}{Δ t} ( {w}_{1}^{e} ⋯ {w}_{{n}_{e}}^{e} ) ( \begin{matrix}{\int }_{V} {\vec{N}}_{1}^{e} \cdot {\vec{N}}_{1}^{e} dV & ⋯ & {\int }_{V} {\vec{N}}_{1}^{e} \cdot {\vec{N}}_{{n}_{e}}^{e} dV \\ ⋮ & ⋱ & ⋮ \\ {\int }_{V} {\vec{N}}_{{n}_{e}}^{e} \cdot {\vec{N}}_{1}^{e} dV & ⋯ & {\int }_{V} {\vec{N}}_{{n}_{e}}^{e} \cdot {\vec{N}}_{{n}_{e}}^{e} dV\end{matrix} ) ( \begin{matrix}{A}_{1}^{n + 1} - {A}_{1}^{n} \\ ⋮ \\ {A}_{{n}_{e}}^{n + 1} - {A}_{{n}_{e}}^{n}\end{matrix} ) = \frac{{σ}_{1}}{Δ t} {{\{ {w}^{e} \}}_{i} [ {\vec{N}}^{e} \cdot {\vec{N}}^{e} ]}_{ij} {\{ {A}^{n + 1} - {A}^{n} \}}_{j} & ( 28 ) \\ {σ}_{1} ( {w}_{1}^{e} ⋯ {w}_{{n}_{e}}^{e} ) ( \begin{matrix}{\int }_{V} {\vec{N}}_{1}^{e} \cdot ∇ {N}_{1}^{n} dV & ⋯ & {\int }_{V} {\vec{N}}_{1}^{e} \cdot ∇ {N}_{{n}_{n}}^{n} dV \\ ⋮ & ⋱ & ⋮ \\ {\int }_{V} {\vec{N}}_{{n}_{e}}^{e} \cdot ∇ {N}_{1}^{n} dV & ⋯ & {\int }_{V} {\vec{N}}_{{n}_{e}}^{e} \cdot ∇ {N}_{{n}_{n}}^{n} dV\end{matrix} ) ( \begin{matrix}{ϕ}_{1}^{n + 1} \\ ⋮ \\ {ϕ}_{{n}_{n}}^{n + 1}\end{matrix} ) = {σ}_{1} {{\{ {w}^{e} \}}_{i} [ {\vec{N}}^{e} \cdot ∇ {N}^{n} ]}_{ij} {\{ {ϕ}^{n + 1} \}}_{j} & ( 29 ) \\ \frac{{σ}_{1} r}{{ɛ}_{r} {ɛ}_{0}} ( {w}_{1}^{e} ⋯ {w}_{{n}_{e}}^{e} ) ( \begin{matrix}{\int }_{V} {\vec{N}}_{1}^{e} \cdot \vec{q} dV \\ ⋮ \\ {\int }_{V} {\vec{N}}_{{n}_{e}}^{e} \cdot \vec{q} dV\end{matrix} ) = \frac{{σ}_{1} r}{{ɛ}_{r} {ɛ}_{0}} {{\{ {w}^{e} \}}_{i} [ {\vec{N}}^{e} \cdot \vec{q} ]}_{i} & ( 30 ) \\ \frac{1}{μ} ( {w}_{1}^{e} ⋯ {w}_{{n}_{e}}^{e} ) ( \begin{matrix}{\int }_{V} ∇ \times {\vec{N}}_{1}^{e} \cdot ∇ \times {\vec{N}}_{1}^{e} dV & ⋯ & {\int }_{V} ∇ \times {\vec{N}}_{1}^{e} \cdot ∇ \times {\vec{N}}_{{n}_{e}}^{e} dV \\ ⋮ & ⋱ & ⋮ \\ {\int }_{V} ∇ \times {\vec{N}}_{{n}_{e}}^{e} \cdot ∇ \times {\vec{N}}_{1}^{e} dV & ⋯ & {\int }_{V} ∇ \times {\vec{N}}_{{n}_{e}}^{e} \cdot ∇ \times {\vec{N}}_{{n}_{e}}^{e} dV\end{matrix} ) ( \begin{matrix}{A}_{1}^{n + 1} \\ ⋮ \\ {A}_{{n}_{e}}^{n + 1}\end{matrix} ) = {σ}_{1} {{\{ {w}^{e} \}}_{i} [ {\vec{N}}^{e} \cdot ∇ {N}^{n} ]}_{ij} {\{ {ϕ}^{n + 1} \}}_{j} = \frac{1}{μ} {{\{ {w}^{e} \}}_{i} [ ∇ \times {\vec{N}}^{e} ∇ \times {\vec{N}}^{e} ]}_{ij} {\{ {A}^{n + 1} \}}_{j} & ( 31 ) \\ ( {w}_{1}^{e} ⋯ {w}_{{n}_{e}}^{e} ) ( \begin{matrix}{\int }_{V} {\vec{N}}_{1}^{e} \cdot {\vec{J}}_{0} dV \\ ⋮ \\ {\int }_{V} {\vec{N}}_{{n}_{e}}^{e} \cdot {\vec{J}}_{0} dV\end{matrix} ) = {\{ {w}^{e} \}}_{i} [ {\vec{N}}^{e} \cdot {\vec{J}}_{0} ] & ( 32 )\end{matrix}$$

If Formulas (27) to (32) are combined, Formula (33) is obtained. From Formula (33), there is generated a system of simultaneous equations including a number of equations corresponding to the number of edges included in the model 70.

$$\frac{{σ}_{1}}{Δ t} {{\{ {w}^{e} \}}_{i} [ {\vec{N}}^{e} \cdot {\vec{N}}^{e} ]}_{ij} {\{ {A}^{n + 1} \}}_{j} + {σ}_{1} {{\{ {w}^{e} \}}_{i} [ {\vec{N}}^{e} \cdot ∇ {N}^{e} ]}_{ij} {\{ {ϕ}^{n + 1} \}}_{j} + \frac{1}{μ} {{\{ {w}^{e} \}}_{i} [ ∇ \times {\vec{N}}^{e} \cdot ∇ \times {\vec{N}}^{e} ]}_{ij} {\{ {A}^{n + 1} \}}_{j} = \frac{{σ}_{1}}{Δ t} {{\{ {w}^{e} \}}_{i} [ {\vec{N}}^{e} \cdot {\vec{N}}^{e} ]}_{ij} {\{ {A}^{n} \}}_{j} + \frac{{σ}_{1} r}{{ɛ}_{r} {ɛ}_{0}} {{\{ {w}^{e} \}}_{i} [ {\vec{N}}^{e} \cdot \vec{q} ]}_{i} + {{\{ {w}^{e} \}}_{i} [ {\vec{N}}^{e} \cdot {\vec{J}}_{0} ]}_{i} \qquad ( 33 )$$

Similarly, in Formula (20), which is one of the basic equations, Formula (24) is substituted in for the vector potential A, and Formula (25) is substituted in for the scalar potential φ. Both sides of Formula (20) are multiplied by a weighting function N defined by Formula (34), and spatially integrated. In Formula (34), Nⁿᵢ is an interpolation function similar to Formula (25), while wⁿᵢ is a scalar value expressing the weight of a node.

The first term on the left side of the formula computed by the above calculation may be expanded as in Formula (35) using matrices. Herein, {wⁿ} is a matrix of the size 1×(number of nodes), [∇Nⁿ·N^{e}] is a matrix of the size (number of nodes)×(number of edges), and {Aⁿ⁺¹-Aⁿ} is a matrix of the size (number of edges)×1. The second term on the left side of the computed formula may be expanded as in Formula (36) using matrices. Herein, [∇Nⁿ·∇Nⁿ] is a matrix of the size (number of nodes)×(number of nodes), and {φⁿ⁺¹} is a matrix of the size (number of nodes)×1. The third term on the left side of the computed formula may be expanded as in Formula (37) using a matrix. Herein, [∇Nⁿ·q] is a matrix of the size (number of nodes)×1.

$$\begin{matrix}N = {\sum }_{i = 1}^{{n}_{n}} {w}_{i}^{n} {N}_{i}^{n} & ( 34 ) \\ - \frac{{σ}_{1}}{Δ t} ( {w}_{1}^{n} ⋯ {w}_{{n}_{n}}^{n} ) ( \begin{matrix}{\int }_{V} ∇ {N}_{1}^{n} \cdot {\vec{N}}_{1}^{e} dV & ⋯ & {\int }_{V} ∇ {N}_{1}^{n} \cdot {\vec{N}}_{{n}_{e}}^{e} dV \\ ⋮ & ⋱ & ⋮ \\ {\int }_{V} ∇ {N}_{{n}_{n}}^{n} \cdot {\vec{N}}_{1}^{e} dV & ⋯ & {\int }_{V} ∇ {N}_{{n}_{n}}^{n} \cdot {\vec{N}}_{{n}_{e}}^{e} dV\end{matrix} ) ( \begin{matrix}{A}_{1}^{n + 1} - {A}_{1}^{n} \\ ⋮ \\ {A}_{{n}_{e}}^{n + 1} - {A}_{{n}_{e}}^{n}\end{matrix} ) = - \frac{{σ}_{1}}{Δ t} {{\{ {w}^{n} \}}_{i} [ ∇ {N}^{n} \cdot {\vec{N}}^{e} ]}_{ij} {\{ {A}^{n + 1} - {A}^{n} \}}_{j} & ( 35 ) \\ - {σ}_{1} ( {w}_{1}^{n} ⋯ {w}_{{n}_{n}}^{n} ) ( \begin{matrix}{\int }_{V} ∇ {N}_{1}^{n} \cdot ∇ {N}_{1}^{n} dV & ⋯ & {\int }_{V} {\vec{N}}_{1}^{e} \cdot ∇ {N}_{{n}_{n}}^{n} dV \\ ⋮ & ⋱ & ⋮ \\ {\int }_{V} ∇ {N}_{{n}_{n}}^{n} \cdot ∇ {N}_{1}^{n} dV & ⋯ & {\int }_{V} {N}_{{n}_{n}}^{n} \cdot ∇ {N}_{{n}_{n}}^{n} dV\end{matrix} ) ( \begin{matrix}{ϕ}_{1}^{n + 1} \\ ⋮ \\ {ϕ}_{{n}_{n}}^{n + 1}\end{matrix} ) = {σ}_{1} {{\{ {w}^{n} \}}_{i} [ ∇ {\vec{N}}^{n} \cdot ∇ {N}^{n} ]}_{ij} {\{ {ϕ}^{n + 1} \}}_{j} & ( 36 ) \\ - \frac{{σ}_{1} r}{{ɛ}_{r} {ɛ}_{0}} ( {w}_{1}^{n} ⋯ {w}_{{n}_{n}}^{n} ) ( \begin{matrix}{\int }_{V} ∇ {N}_{1}^{n} \cdot \vec{q} dV \\ ⋮ \\ {\int }_{V} ∇ {N}_{{n}_{n}}^{n} \cdot \vec{q} dV\end{matrix} ) = - \frac{{σ}_{1} r}{{ɛ}_{r} {ɛ}_{0}} {{\{ {w}^{n} \}}_{i} [ ∇ {N}^{n} \cdot \vec{q} ]}_{i} & ( 37 )\end{matrix}$$

If Formulas (35) to (37) are combined, Formula (38) is obtained. From Formula (38), there is generated a system of simultaneous equations including a number of equations corresponding to the number of nodes included in the model 70.

$$\frac{{σ}_{1}}{Δ t} {{\{ {w}^{n} \}}_{i} [ ∇ {N}^{n} \cdot {\vec{N}}^{e} ]}_{ij} {\{ {A}^{n + 1} \}}_{j} + {σ}_{1} {{\{ {w}^{n} \}}_{i} [ ∇ {N}^{n} \cdot ∇ {N}^{n} ]}_{ij} {\{ {ϕ}^{n + 1} \}}_{j} = \frac{{σ}_{1}}{Δ t} {{\{ {w}^{n} \}}_{i} [ ∇ {N}^{n} \cdot {\vec{N}}^{e} ]}_{ij} {\{ {A}^{n} \}}_{j} - \frac{{σ}_{1} r}{{ɛ}_{r} {ɛ}_{0}} {{\{ {w}^{e} \}}_{i} [ ∇ {N}^{n} \cdot \vec{q} ]}_{i} \qquad ( 33 )$$

If the above Formulas (35) and (38) are united and combined, Formula (45) is obtained as the final system of simultaneous equations. Formula (45) expresses that the product of a coefficient matrix G and a solution vector X is equal to a right-hand side vector F. The coefficient matrix G is the union of the four partial coefficient matrices G_{AA}, G_{Aφ}, G_{φA}, and G_{φφ}. The partial coefficient matrix G_{AA} is a matrix of the size (number of edges)×(number of edges) defined by Formula (39). The partial coefficient matrix G_{Aφ} is a matrix of the size (number of edges)×(number of nodes) defined by Formula (40). The partial coefficient matrix G_{φA} is a matrix of the size (number of nodes)×(number of edges) defined by Formula (41). The partial coefficient matrix G_{φφ} is a matrix of the size (number of nodes)×(number of nodes) defined by Formula (42).

In the coefficient matrix G, G_{AA} is disposed in the upper-left, G_{Aφ} is disposed in the upper-right, G_{φA} is disposed in the lower-left, and G_{φφ} is disposed in the lower-right. The coefficient matrix G is a square matrix in which the length of one edge is (number of edges)+(number of nodes). The solution vector X is a column vector in which the unknown vector potentials A assigned to the edges of the model 70 and the unknown scalar potentials φ assigned to the nodes of the model 70 are arranged. The solution vector X corresponds to a variable vector in which the variables of the system of simultaneous equations are arranged. The solution vector X is a column vector in which the number of rows is (number of edges)+(number of nodes).

The right-hand side vector F is the union of two partial vectors F_{A} and F_{φ}. The partial vector F_{A} is a column vector of the size (number of edges)×1 defined by Formula (43). The partial vector F_{A} is computed using the vector potential A and the charge density q of the preceding time. The partial vector F_{φ} is a column vector of the size (number of nodes)×1 defined by Formula (44). The partial vector F_{φ} is computed using the vector potential A and the charge density q of the preceding time. In the right-hand side vector F, F_{A} is disposed on the top, and F_{φ} is disposed on the bottom. The right-hand side vector F is a column vector in which the number of rows is (number of edges)+(number of nodes).

$$\begin{matrix}{G}_{AA} = {\frac{{σ}_{1}}{Δ t} [ {\vec{N}}^{e} \cdot {\vec{N}}^{e} ]}_{ij} + {\frac{1}{μ} [ ∇ \times {\vec{N}}^{e} \cdot ∇ \times {\vec{N}}^{e} ]}_{ij} & ( 39 ) \\ {G}_{A ϕ} = {{σ}_{1} [ {\vec{N}}^{e} \cdot ∇ {N}^{n} ]}_{ij} & ( 40 ) \\ {G}_{ϕ A} = {{σ}_{1} [ ∇ {N}^{n} \cdot {\vec{N}}^{e} ]}_{ij} & ( 41 ) \\ {G}_{ϕϕ} = {σ}_{1} Δ {t [ ∇ {N}^{n} \cdot ∇ {N}^{n} ]}_{ij} & ( 42 ) \\ {F}_{A} = {\frac{{σ}_{1}}{Δ t} [ {\vec{N}}^{e} \cdot {\vec{N}}^{e} ]}_{ij} {\{ {A}^{n} \}}_{j} + {\frac{{σ}_{1} r}{{ɛ}_{r} {ɛ}_{0}} [ {\vec{N}}^{e} \cdot \vec{q} ]}_{i} + {[ {\vec{N}}^{e} \cdot {\vec{J}}_{0} ]}_{i} & ( 43 ) \\ {F}_{ϕ} = {{σ}_{1} [ ∇ {N}^{n} \cdot {\vec{N}}^{e} ]}_{ij} {\{ {A}^{n} \}}_{j} - {\frac{{σ}_{1} r Δ t}{{ɛ}_{r} {ɛ}_{0}} [ ∇ {N}^{n} \cdot \vec{q} ]}_{i} & ( 44 ) \\ ( \begin{matrix}{G}_{AA} & {G}_{A ϕ} \\ {G}_{ϕ A} & {G}_{ϕϕ}\end{matrix} ) \{ \begin{matrix}\{ {A}^{n + 1} \} \\ \{ {ϕ}^{n + 1} \}\end{matrix} \} = ( \begin{matrix}\{ {F}_{A} ( {A}^{n} , {\vec{q}}^{n} ) \} \\ \{ {F}_{A} ( {A}^{n} , {\vec{q}}^{n} ) \}\end{matrix} ) & ( 45 )\end{matrix}$$

In this way, in accordance with the basic equations, namely Formulas (19) and (20), there is generated a system of simultaneous equations including equations corresponding to the sum of the number of edges and the number of nodes included in the model 70, for example, the sum of the number of unknown vector potentials and the number of unknown scalar potentials. The solution to the system of simultaneous equations indicated by Formula (45) may be computed by an iterative method such as the conjugate gradient (CG) method or the incomplete Cholesky CG (ICCG) method.

Formula (18) indicating the current density i₁ may be transformed as in Formula (46) in a discrete time simulation. From the vector potential Aⁿ⁺¹ at the time n+1, the scalar potential φⁿ⁺¹ at the time n+1, the vector potential Aⁿ at the time n, and the charge density qⁿ at the time n, the current density i₁ⁿ⁺¹ of each element at the time n+1 is computed in accordance with Formula (46). From the current density i₁ⁿ⁺¹ at the time n+1 and the charge density qⁿ at the time n, the charge density qⁿ⁺¹ of each element at the time n+1 is computed in accordance with Formula (23) described earlier.

$${\vec{i}}_{1}^{n + 1} = - {σ}_{1} ( \frac{1}{Δ t} {\sum }_{i = 1}^{{n}_{e}} {\vec{N}}_{i}^{e} ( {A}_{i}^{n + 1} - {A}_{i}^{n} ) - {\sum }_{i = 1}^{{n}_{n}} ∇ {N}_{i}^{n} {ϕ}_{i}^{n + 1} + \frac{r}{{ɛ}_{r} {ɛ}_{0}} {\vec{q}}^{n} ) \qquad ( 46 )$$

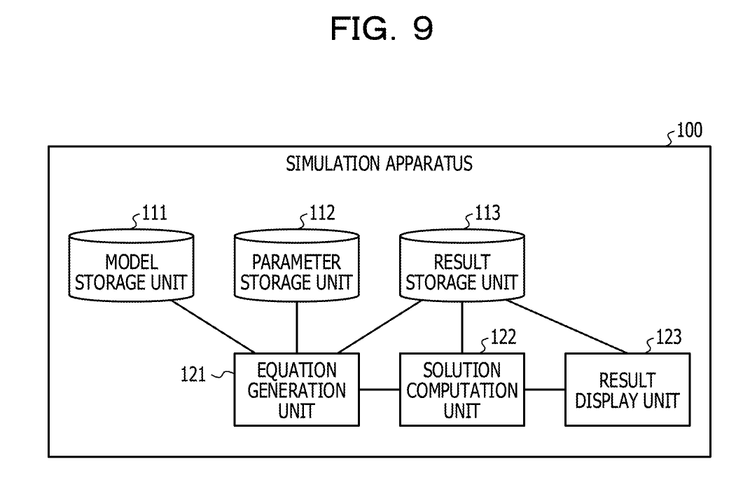

FIG. 9 illustrates exemplary functions of a simulation apparatus. The simulation apparatus 100 includes a model storage unit 111, a parameter storage unit 112, a result storage unit 113, an equation generation unit 121, a solution computation unit 122, and a result display unit 123. The model storage unit 111, the parameter storage unit 112, and the result storage unit 113 are implemented using a storage area reserved in the RAM 102 or the HDD 103, for example. The equation generation unit 121, the solution computation unit 122, and the result display unit 123 are implemented using a program module executed by the CPU 101, for example.

The model storage unit 111 stores model data indicating the multiple elements included in the model 70. The model data may be generated based on user operations, or may be generated automatically by software such as modeling software. The model data may be generated by the simulation apparatus 100, or may be generated by another apparatus.

The parameter storage unit 112 stores various parameters used in the simulation. The parameters are specified by the user, for example. The parameters include parameters indicating running conditions, such as the frequency of the current flowing through the coil 42. The parameters include physical property values indicating physical properties, such as the conductivity of the magnetic material. The parameters include parameters indicating simulation conditions, such as the time width of the simulation.

The result storage unit 113 stores simulation results. The simulation results include vector potentials, scalar potentials, current densities, and charge densities. The equation generation unit 121 assigns variables to multiple positions in the model 70, based on the model data stored in the model storage unit 111. The equation generation unit 121 assigns vector potential variables to the edges of the elements, and assigns scalar potential variables to the nodes of the elements. Additionally, the equation generation unit 121 uses the parameters stored in the parameter storage unit 112 and the simulation results of the preceding step stored in the result storage unit 113 to generate a system of simultaneous equations that obtains a solution to the variables. The equation generation unit 121 repeats the generation of the system of simultaneous equations along the time axis, in accordance with the parameters.

The solution computation unit 122 uses an iterative method to solve the system of simultaneous equations generated by the equation generation unit 121, and obtains an approximate solution to the variables. The solution computation unit 122 obtains an approximate solution to the vector potentials of the edges of the elements, and an approximate solution to the scalar potentials of the nodes of the elements. Also, the solution computation unit 122 uses the most recent vector potentials and scalar potentials as well as the simulation results of the preceding step stored in the result storage unit 113 to compute the current density and the charge density of each element. The solution computation unit 122 saves the vector potentials, the scalar potentials, the current densities, and the charge densities of the most recent step in the result storage unit 113.

When the iterative processes by the equation generation unit 121 and the solution computation unit 122 end, the result display unit 123 causes the display 31 to display the simulation results stored in the result storage unit 113. At this time, the result display unit 123 may also cause the display 31 to display numerical values included in the simulation results. In addition, the result display unit 123 may also cause the display 31 to display a visualization image converted from the simulation results. The result display unit 123 may also output the simulation results to an output apparatus other than the display 31.

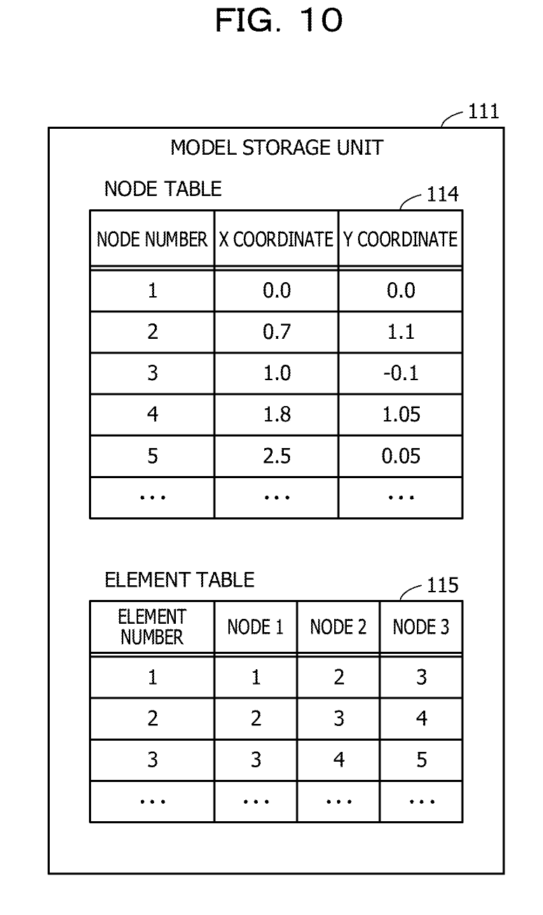

FIG. 10 illustrates an exemplary node table and an element table. A node table 114 is stored in the model storage unit 111. The node table 114 includes node number, X coordinate, and Y coordinate fields. The node number is an identification number of a node. The X coordinate and the Y coordinate are coordinates indicating the position of a node in an orthogonal coordinate system. In the case in which the model 70 is a three-dimensional mode, the node table 114 additionally includes a Z coordinate field.

A element table 115 is stored in the model storage unit 111. The element table 115 includes element number, Node 1, Node 2, and Node 3 fields. The element number is an identification number of an element. Node 1, Node 2, and Node 3 indicate the node numbers of nodes forming an element. An edge that forms the element may be identified by a pair of two nodes forming the element. In the case in which the element is a tetrahedron, the element table 115 additionally includes a Node 4 field. For example, node numbers equal to the number of nodes forming an element are associated with a single element number.

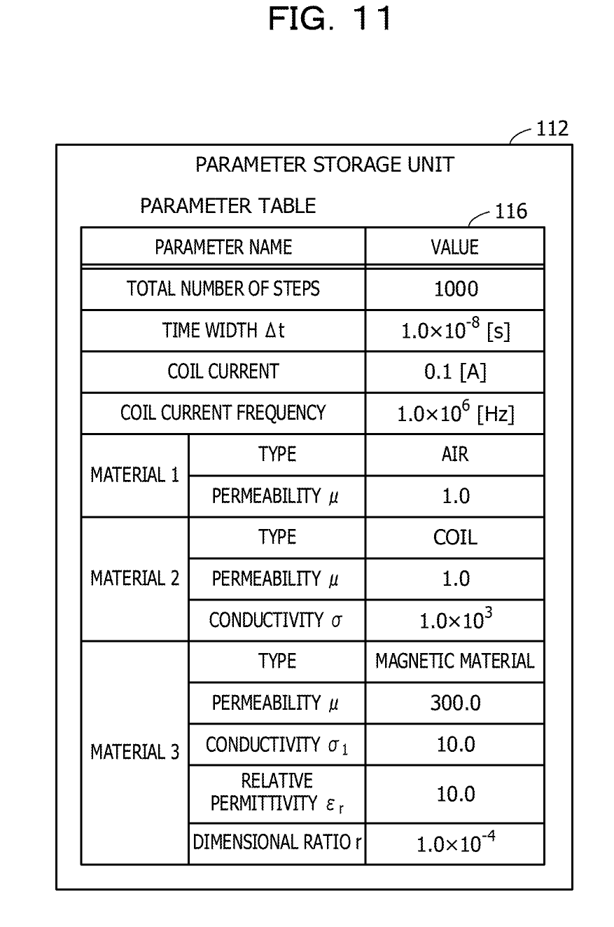

FIG. 11 illustrates an exemplary parameter table. The parameter table 116 is stored in the parameter storage unit 112. The parameter table 116 associates parameter names and their values.

The parameters include a total number of steps and a time width Δt. The total number of steps is the number of discrete times in the simulation, and for example, expresses the number of repetitions of the process of generating a system of simultaneous equations and obtaining a solution. The time width Δt is the time difference in the simulation between a certain step and the next step, or in other words, expresses the minimum unit of the passage of time.

The parameters include a coil current and a coil current frequency. The coil current expresses the amplitude of the current flowing through the coil 42. The coil current frequency expresses the frequency of the current flowing through the coil 42. Assuming that the current flowing through the coil 42 varies sinusoidally, the current density J₀ of the coil 42 at each time may be computed from the coil current and the coil current frequency. The current density J₀ of each time may also be recorded in the parameter table 116.

The parameters include physical property values for each of multiple materials. Material 1 is the air existing around the toroidal core 41 and the coil 42. The parameters related to air include the permeability μ. Material 2 is the material of the coil 42. The parameters related to the coil 42 include the permeability μ and the conductivity σ. Material 3 is the magnetic material used in the toroidal core 41. The parameters related to the magnetic material include the permeability μ, the conductivity σ₁, the relative permittivity εᵣ, and the dimensional ratio r. Although the parameters of three materials are stated, the parameters of one or more materials are stated in the parameter table 116, in accordance with the analysis target.

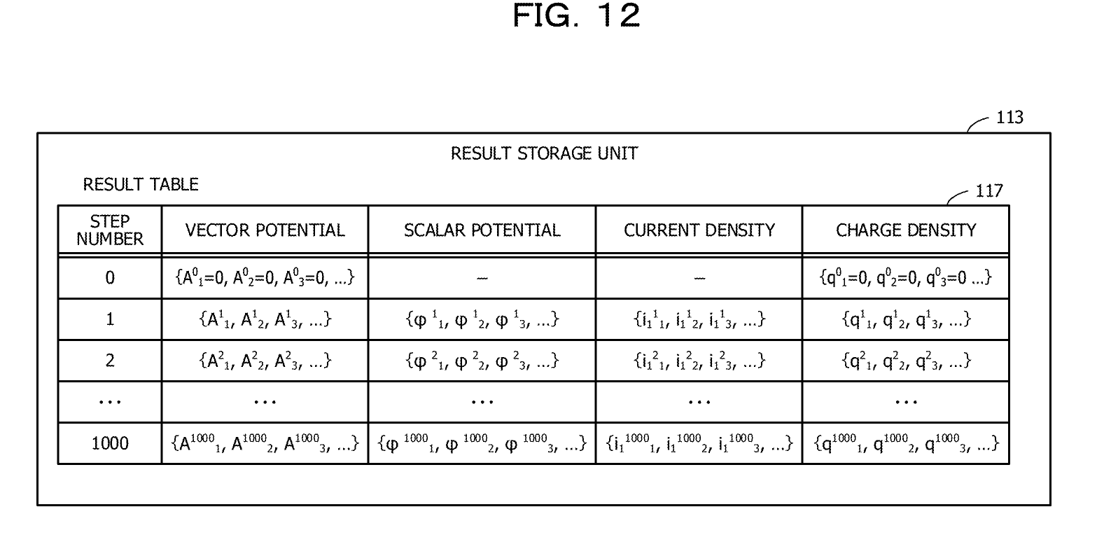

FIG. 12 is a diagram illustrating an exemplary result table. The result table 117 is stored in the result storage unit 113. The result table 117 includes step number, vector potential, scalar potential, current density, and charge density fields. The step number is a number that identifies each step (each time) of the simulation, and is an integer equal to or greater than 0, and less than or equal to the total number of steps.

The vector potential field lists the vector potentials of the multiple edges computed in a certain step. The vector potential of each edge in step 0 is initialized to 0. The scalar potential field lists the scalar potentials of the multiple nodes computed in a certain step. The scalar potentials in step 0 do not have to be computed. The current density field lists the current densities of the multiple elements computed in a certain step. The current densities in step 0 do not have to be computed. The charge density field lists the charge densities of the multiple elements computed in a certain step. However, the charge density of each element in step 0 is initialized to 0.

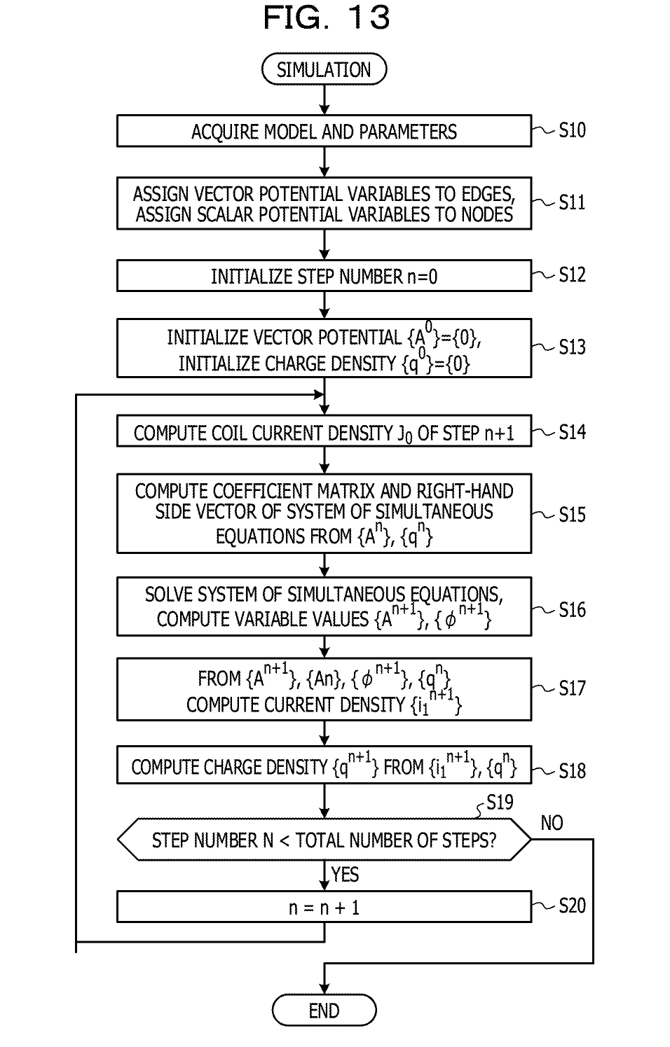

FIG. 13 illustrates an exemplary procedure of a simulation.

(S10) The equation generation unit 121 reads out model data from the model storage unit 111. The equation generation unit 121 reads out parameters from the parameter storage unit 112.

(S11) The equation generation unit 121 assigns a vector potential variable (a variable indicating an unknown vector potential A) to each of the multiple edges indicated by the model data. The equation generation unit 121 assigns a scalar potential variable (a variable indicating an unknown scalar potential φ) to each of the multiple nodes indicated by the model data.

(S12) The equation generation unit 121 initializes the step number n to 0. The equation generation unit 121 specifies the total number of steps (an upper limit on the number of steps) indicated by the parameters.

(S13) The solution computation unit 122 initializes the value (vector potential A⁰) in step 0 of the vector potential variable assigned in step S11 to 0. The solution computation unit 122 initializes the charge density q⁰ in step 0 of each of the multiple elements indicated by the model data to 0. The solution computation unit 122 registers the vector potential A⁰ and the charge density q⁰ in the result table 117 stored in the result storage unit 113.

(S14) The equation generation unit 121 computes the current density J₀ of the coil 42 in step n+1, based on the parameters read out in step S10.

(S15) The equation generation unit 121, following Formula (45), generates the coefficient matrix G and the right-hand side vector F indicating the system of simultaneous equations corresponding to step n+1. In the generation of the coefficient matrix G, the parameters read out in step S10 are used. In the generation of the right-hand side vector F, the current density J₀ computed in step S14 and the parameters read out in step S10 are used. Additionally, in the generation of the right-hand side vector F, the vector potential Aⁿ and the charge density qⁿ of step n stored in the result table 117 are used.

(S16) The solution computation unit 122 computes a solution to the system of simultaneous equations generated in step S15 with an iterative method such as the CG method or the ICCG method. With this arrangement, the vector potential Aⁿ⁺¹ and the scalar potential φⁿ⁺¹ of step n+1 are computed. The solution computation unit 122 registers the vector potential Aⁿ⁺¹ and the scalar potential φⁿ⁺¹ in the result table 117.

(S17) The solution computation unit 122, following Formula (46), computes the current density i₁ⁿ⁺¹ of each element in step n+1. In the computation of the current density i₁ⁿ⁺¹, the read-out parameters, the vector potential Aⁿ⁺¹ of step n+1, the vector potential Aⁿ of step n, the scalar potential φⁿ⁺¹ of step n+1, and the charge density qⁿ of step n are used. The solution computation unit 122 registers the current density i₁ⁿ⁺¹ in the result table 117.

(S18) The solution computation unit 122, following Formula (23), computes the charge density qⁿ⁺¹ of each element in step n+1. In the computation of the charge density qⁿ⁺¹, the read-out parameters, the current density i₁¹¹⁺¹ of step n+1, and the charge density qⁿ of step n are used. The solution computation unit 122 registers the charge density qⁿ⁺¹ in the result table 117.

(S19) The equation generation unit 121 determines whether the current step number n is less than the total number of steps. In the case in which the step number n is less than the total number of steps, the process proceeds to step S20, whereas in the case in which the step number n has reached the total number of steps, the simulation ends.

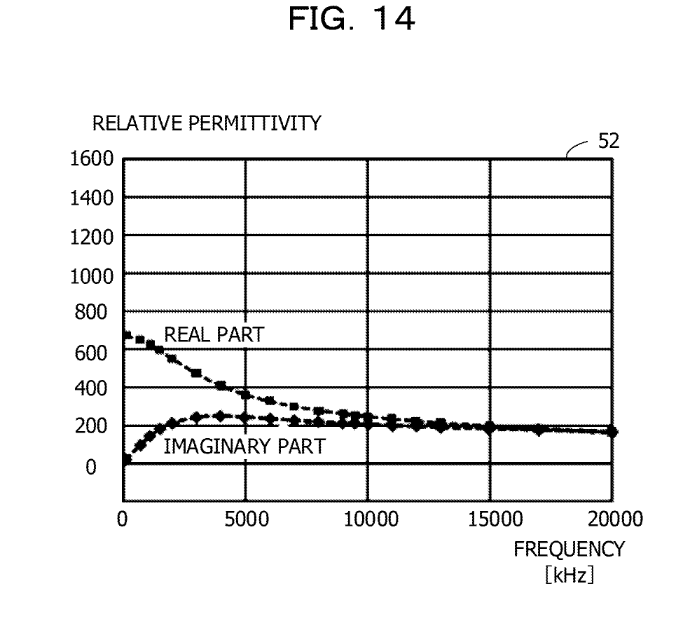

(S20) The equation generation unit 121 increments the step number n by 1, and proceeds to step S14. FIG. 14 illustrates an exemplary simulation that does not account for a dimensional resonance phenomenon.

In the case of performing a simulation that does not account for the capacitance effect of the grain boundary layer 62, in which the dimensional resonance phenomenon is not reproduced, a simulation result like the graph 52 is obtained. The simulation that does not account for the capacitance effect is a simulation using Formulas (15) to (17) described above as the basic equations. Similarly to the graph 51 described above, the graph 52 illustrates the relationship between the frequency of current flowing through the coil 42 and the relative permeability of the toroidal core 41. Unlike the actual relative permeability of the toroidal core 41 illustrated by the graph 51, the graph 52 does not express the increase in the real part and the increase in the imaginary part of the relative permeability, and does not reproduce the dimensional resonance phenomenon.

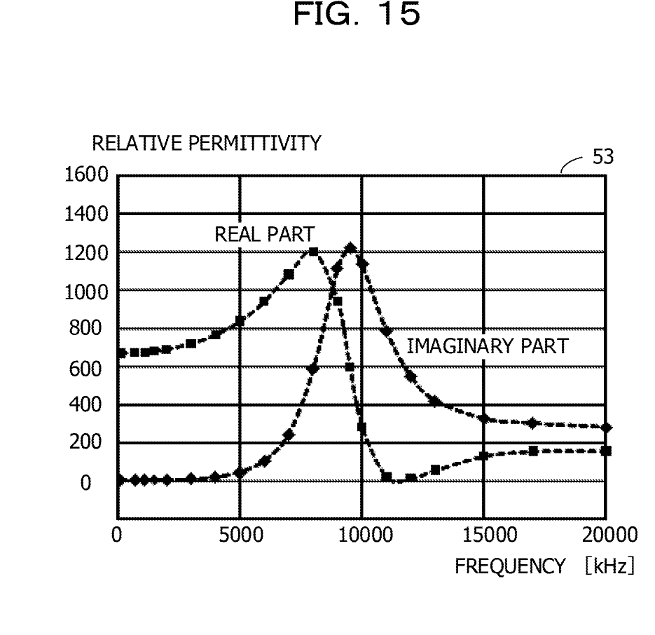

FIG. 15 illustrates an exemplary simulation that accounts for the dimensional resonance phenomenon. In the case of performing a simulation that accounts for the capacitance effect of the grain boundary layer 62, in which the dimensional resonance phenomenon is reproduced, a simulation result like the graph 53 is obtained. The simulation that accounts for the capacitance effect is a simulation using Formulas (18) to (20) and (23) described above as the basic equations. Similarly to the graphs 51 and 52 described above, the graph 53 illustrates the relationship between the frequency of current flowing through the coil 42 and the relative permeability of the toroidal core 41. Similarly to the actual relative permeability of the illustrated by the graph 51, the graph 53 expresses the increase in the real part and the increase in the imaginary part of the relative permeability, and reproduces the dimensional resonance phenomenon. In the graph 53, the peak frequency at which the real part of the relative permeability reaches a maximum and the peak frequency at which the imaginary part reaches a maximum sufficiently approximate the actual peak frequencies illustrated by the graph 51.

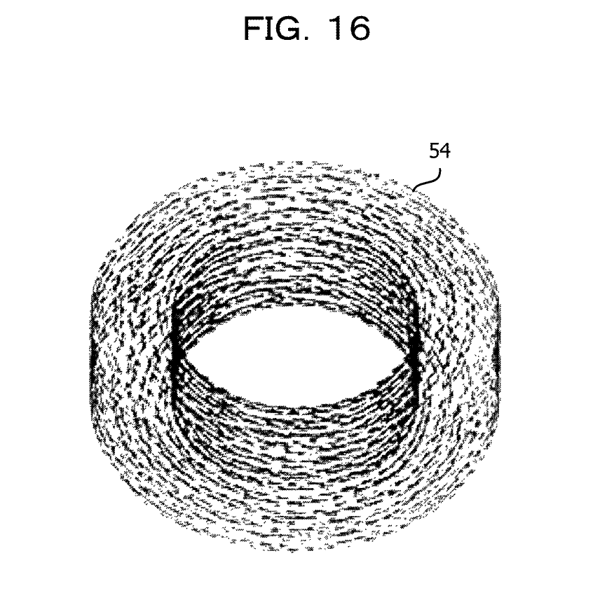

FIG. 16 illustrates an exemplary magnetic flux density visualization image. As described above, the result display unit 123 is capable of converting result data registered in the result table 117 into a visualization image, and display the visualization image on the display 31. An exemplary visualization image which may be generated by the result display unit 123 is a magnetic flux density visualization image 54 like in FIG. 16. The magnetic flux density visualization image 54 uses arrows to express the magnitude and direction of the magnetic flux density inside the toroidal core 41. The magnetic flux density may be computed from the vector potentials A.

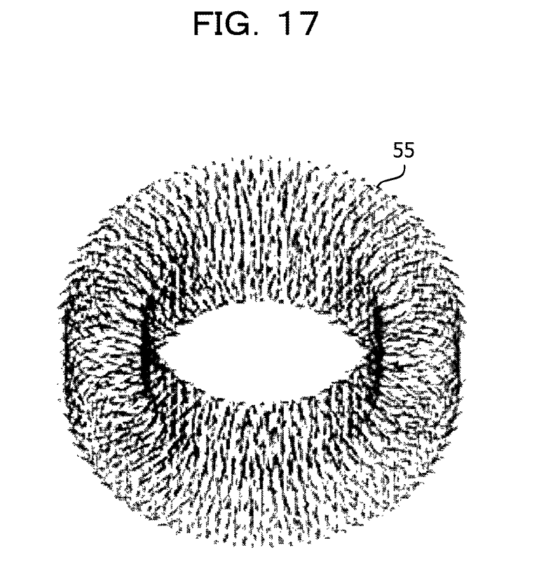

FIG. 17 illustrates an exemplary current density visualization image. Another exemplary visualization image which may be generated by the result display unit 123 is a current density visualization image 55 like in FIG. 17. The current density visualization image 55 uses arrows to express the magnitude and direction of the eddy current density i inside the toroidal core 41.

According to the simulation apparatus 100 illustrated in FIG. 2, in the magnetic material simulation using the finite element method, the capacitance effect of the grain boundary layer 62 is expressed as the charge density q of charge accumulated in each element, and the charge density q is added to the basic equations related to the magnetic field. The vector potential Aⁿ⁺¹ and the scalar potential φn+1 at the time n+1 are computed from the vector potential Aⁿ and the charge density qⁿ at the time n. The current density i₁ⁿ (eddy current density) of each element at the time n+1 is computed from vector potential Aⁿ⁺¹ and the scalar potential φⁿ⁺¹ at the time n+1, and the vector potential Aⁿ and the charge density qⁿ at the time n. The charge density qⁿ⁺¹ of each element at the time n+1 is computed from the current density i₁ at the time n+1 and the charge density q at the time n, and is used in the calculation of the time n+2.

With this arrangement, the dimensional resonance phenomenon produced in a polycrystalline magnetic material may be reproduced, and the accuracy of the magnetic material simulation may be improved.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A non-transitory computer-readable recording medium recording a magnetic material simulation program causing a computer to execute a process, the process comprising:
acquiring a shape model that includes a plurality of element regions generated by partitioning a shape of a core, property information indicating physical properties of a magnetic material used in the core, and coil current information indicating a time change in a current flowing through a coil wrapped around the core;
specifying a first current density of the coil at a first time, based on the coil current information;
computing, using the property information and the first current density, a plurality of first index values related to a magnetic field at the first time, in correspondence with a plurality of positions in the shape model;
computing, using the plurality of first index values, a charge density of each of the plurality of element regions;
specifying a second current density of the coil at a second time after the first time, based on the coil current information; and
computing, using the property information, the second current density, and the charge density of each of the plurality of element regions, a plurality of second index values related to a magnetic field at the second time, in correspondence with the plurality of positions.

2. The non-transitory computer-readable recording medium according to claim 1, further comprising:
computing, in the computing of the charge density, a third current density of each of the plurality of element regions at the first time using the plurality of first index values; and
computing, using the third current density, the charge density of each of the plurality of element regions.

3. The non-transitory computer-readable recording medium according to claim 1, further comprising:
computing, using the plurality of second index values and the charge density, a fourth current density of each of the plurality of element regions at the second time; and
computing, using the fourth current density and the charge density, an other charge density of each of the plurality of element regions.

4. The non-transitory computer-readable recording medium according to claim 1, wherein
the property information includes size information indicating a relationship between a thickness of each of a plurality of crystal grains included in the magnetic material, and a thickness of a grain boundary layer existing between the plurality of crystal grains.

5. The non-transitory computer-readable recording medium according to claim 1, wherein
the plurality of first index values and the plurality of second index values include at least one of a vector potential and a scalar potential.

6. A magnetic material simulation method comprising:
acquiring, by a computer, a shape model that includes a plurality of element regions generated by partitioning a shape of a core, property information indicating physical properties of a magnetic material used in the core, and coil current information indicating a time change in a current flowing through a coil wrapped around the core;
specifying a first current density of the coil at a first time, based on the coil current information;
computing, using the property information and the first current density, a plurality of first index values related to a magnetic field at the first time, in correspondence with a plurality of positions in the shape model;
computing, using the plurality of first index values, a charge density of each of the plurality of element regions;
specifying a second current density of the coil at a second time after the first time, based on the coil current information; and
computing, using the property information, the second current density, and the charge density of each of the plurality of element regions, a plurality of second index values related to a magnetic field at the second time, in correspondence with the plurality of positions.

7. The magnetic material simulation method according to claim 6, further comprising:
computing, in the computing of the charge density, a third current density of each of the plurality of element regions at the first time using the plurality of first index values; and
computing, using the third current density, the charge density of each of the plurality of element regions.

8. The magnetic material simulation method according to claim 6, further comprising:
computing, using the plurality of second index values and the charge density, a fourth current density of each of the plurality of element regions at the second time; and
computing, using the fourth current density and the charge density, an other charge density of each of the plurality of element regions.

9. The magnetic material simulation method according to claim 6 wherein
the property information includes size information indicating a relationship between a thickness of each of a plurality of crystal grains included in the magnetic material, and a thickness of a grain boundary layer existing between the plurality of crystal grains.

10. The magnetic material simulation method according to claim 6, wherein
the plurality of first index values and the plurality of second index values include at least one of a vector potential and a scalar potential.

11. An information processing apparatus comprising:
a memory that stores a magnetic material simulation program; and
a processor that performs, based on the magnetic material simulation program, operations of:
acquiring a shape model that includes a plurality of element regions generated by partitioning a shape of a core, property information indicating physical properties of a magnetic material used in the core, and coil current information indicating a time change in a current flowing through a coil wrapped around the core;
specifying a first current density of the coil at a first time, based on the coil current information;
computing, using the property information and the first current density, a plurality of first index values related to a magnetic field at the first time, in correspondence with a plurality of positions in the shape model;
computing, using the plurality of first index values, a charge density of each of the plurality of element regions;
specifying a second current density of the coil at a second time after the first time, based on the coil current information; and
computing, using the property information, the second current density, and the charge density of each of the plurality of element regions, a plurality of second index values related to a magnetic field at the second time, in correspondence with the plurality of positions.

12. The information processing apparatus according to claim 11, further comprising:
computing, in the computing of the charge density, a third current density of each of the plurality of element regions at the first time using the plurality of first index values; and
computing, using the third current density, the charge density of each of the plurality of element regions.

13. The information processing apparatus according to claim 11, further comprising:
computing, using the plurality of second index values and the charge density, a fourth current density of each of the plurality of element regions at the second time; and
computing, using the fourth current density and the charge density, an other charge density of each of the plurality of element regions.

14. The information processing apparatus according to claim 11, wherein
the property information includes size information indicating a relationship between a thickness of each of a plurality of crystal grains included in the magnetic material, and a thickness of a grain boundary layer existing between the plurality of crystal grains.

15. The information processing apparatus according to claim 11, wherein
the plurality of first index values and the plurality of second index values include at least one of a vector potential and a scalar potential.
